(19) United States
(12) Patent Application Publication
(10) Pub. No.: US 2020/0333386 A1
(43) Pub. Date: Oct. 22, 2020

(54) POWER MONITORING USING POWER MANAGEMENT INTEGRATED CIRCUITS

(71) Applicant: Google LLC, Mountain View, CA (US)

(72) Inventors: David Bart Bennett, Danville, CA (US); Nathan Connell, Glenview, IL (US); Cheng-Yi Andrew Lin, Mountain View, CA (US); Amin Khajeh Djahromi, Sunnyvale, CA (US)

(21) Appl. No.: 16/852,121

(22) Filed: Apr. 17, 2020

Related U.S. Application Data
(60) Provisional application No. 62/835,839, filed on Apr. 18, 2019.

(51) Int. Cl. G01R 21/133; H03M 1/12; H02M 1/00

(52) U.S. Cl. CPC G01R 21/133; H02M 2001/0045; H02M 1/00; H03M 1/122

(57) ABSTRACT

Methods and apparatus for power monitoring using power management integrated circuits. In some implementations, a power management integrated circuit includes multiple voltage regulators, an analog multiplexer, an analog to digital converter, power determination circuitry, and control circuitry. The analog multiplexer has multiple inputs that are each configured to receive an analog input signal indicative of an amount of electrical current output by a different one of the multiple voltage regulators. The analog-to-digital converter is configured to receive analog output signals from of the analog multiplexer and to provide a digital output. The power determination circuitry configured to determine a power output level for each of the multiple voltage regulators based on respective digital outputs of the analog-to-digital converter. The control circuitry is configured to control the analog multiplexer to periodically change which of the analog input signals is passed to the output of the analog multiplexer.

### CROSS-REFERENCE TO RELATED APPLICATION

This application claims the benefit of U.S. Provisional Application No. 62/835,839, filed Apr. 18, 2019, the contents of which are incorporated by reference herein.

### TECHNICAL FIELD

The present specification relates to power monitoring in power management integrated circuits.

### BACKGROUND

Modern electrical devices often include many different components that use different levels of power. The amount of power consumed by different components and the levels of voltage and current provided to different parts of a device can vary over time.

### SUMMARY

In some implementations, a power management integrated circuit (PMIC) includes integrated power monitoring circuitry that can monitor power provided over multiple different channels. The power monitoring circuitry can be arranged to efficiently monitor multiple different channels in an ongoing or continuous manner using a time-division multiplexing, with power for different channels being monitored in successive time periods. For example, the power monitoring circuitry can include an analog-to-digital converter (ADC) that is fed by the output of an analog multiplexer. The analog multiplexer receives analog input signals representing current and/or voltage for different channels. These channels can represent power rails, such as outputs of voltage regulators integrated into the PMIC and/or outputs from components external to the PMIC. The analog multiplexer can be controlled to periodically change which analog input is passed to the ADC, stepping through each channel to be monitored and repeating the monitoring of the channels on an ongoing basis. The outputs of the ADC are provided to power determination circuitry that can calculate power and energy for the different channels, and provide the power and energy data to a processor, memory, system-on-a-chip (SoC), or other device.

The power monitoring circuitry of the PMIC can provide the versatility to measure power of rails external to the PMIC as well as power output of voltage regulators included in the PMIC. For example, several electrical contacts (e.g., pads or balls) on the PMIC can be used to receive external signals, and these external signals can be routed to one or more ADCs, for example, through an analog multiplexer that may be the same as or different from the analog multiplexer that receives signals for on-chip voltage regulators. In this manner, power for rails supplied by regulators outside the PMIC can be monitored without requiring a power monitoring chip separate from the PMIC. The system can be configured to operate with a single ADC, but is not limited to that configuration. In some implementations, multiple ADCs may be used. As an example, internal power rails or other signals may be routed to one ADC for monitoring, and external rails can be routed to a different ADC.

The power monitoring circuitry can have programmable or adjustable functions to vary the number of power rails and specific set of power rails monitored. For example, the power monitoring circuitry can be arranged to monitor some or all voltage regulators of the PMIC. At different times, or for different operating modes of a device, a processor (e.g., a microcontroller, a central processing unit, etc.) may communicate with the PMIC to cause only subsets of the voltage regulators to be monitored. Similarly, the monitoring period or rate of switching between channels can be varied through external input, as well as whether to monitor power, energy, or both for different channels. In some implementations, multiple channels can be monitored concurrently using the time-division multiplexing approach, e.g., 4 channels, 8 channels, 12 channels, 16 channels, or more according to the needs of particular designs.

The ability to concurrently monitor various individual power rails provides in-field visibility of how and where power is consumed on a device, such as a cellular phone or other mobile device. This improves power debug capability, and provides valuable data for system design and optimization with respect to battery life. Often, mobile devices have constrained circuit board area, routing, and component costs, which can limit the quality of power monitoring and the number of power rails monitored. Integrating power management functionality into the PMIC, as well as using a time-division multiplexing approach can allow many power rails to be monitored without impacting board area, routing, and cost. The ability of a PMIC to additionally monitor external rails (e.g., supplied by regulators outside the PMIC), further relieves these constraints. In addition, the integrated approach using multiplexing can allow substantially continuous monitoring of many rails (e.g., 8, 16, or more) while consuming low power, even in some applications when a device is in a sleep mode or other low-power state.

In one general aspect, a power management integrated circuit includes: multiple voltage regulators; an analog multiplexer having multiple inputs and an output, wherein each of the multiple inputs is configured to receive an analog input signal indicative of an amount of electrical current output by a different one of the multiple voltage regulators; an analog-to-digital converter configured to receive analog output signals from of the analog multiplexer and to provide a digital output; power determination circuitry configured to determine a power output level for each of the multiple voltage regulators based on respective digital outputs of the analog-to-digital converter; and control circuitry configured to control the analog multiplexer to periodically change which of the analog input signals is passed to the output of the analog multiplexer.

In some implementations, to control the analog multiplexer, the control circuitry is configured to send selection signals to the analog multiplexer over multiple monitoring cycles, wherein during each monitoring cycle the selection signals cause each of the multiple inputs to be successively selected with the selection being changed by the control circuitry at a predetermined rate.

In some implementations, the control circuitry is configured to cause the analog multiplexer to repeatedly cycle through the selection of each of the multiple inputs in a series of measurement periods, wherein the selection from the multiple inputs is changed after each measurement period.

In some implementations, the measurement periods have substantially equal durations.

In some implementations, the control circuitry is programmable to vary a rate of changing the selection of which input, from among the multiple inputs of the analog multiplexer, is passed to the output of the analog multiplexer.

In some implementations, the power management integrated circuit is capable of monitoring power output for each of a plurality of channels, and wherein the control circuitry programmable to selectively monitor a proper subset of the plurality of channels.

In some implementations, at least some of the plurality of channels respectively correspond to the multiple voltage regulators, the control circuitry being configured to selectively monitor the channels by controlling the analog multiplexer to select of inputs corresponding to one or more of the multiple voltage regulators.

In some implementations, the power determination circuitry is configured to receive, from the multiple voltage regulators, voltage data indicating output voltages of the multiple voltage regulators. The power determination circuitry is configured to determine power output levels for the multiple voltage regulators based on (i) the digital outputs of the analog-to-digital converter indicating current output of the multiple voltage regulators, and (ii) the voltage data indicating output voltages of the multiple voltage regulators.

In some implementations, the analog multiplexer has additional inputs each configured to receive an analog input signal indicative of a voltage output by a different one of the multiple voltage regulators. The control circuitry is configured to control the analog multiplexer to periodically change which of the analog input signals is passed to the output of the analog multiplexer by varying selection from among a set of inputs comprising the multiple inputs and the additional inputs. The power determination circuitry configured to determine power output levels for the multiple voltage regulators based on (i) the digital outputs of the analog-to-digital converter indicating current output of the multiple voltage regulators, and (ii) the digital outputs of the analog-to-digital converter indicating voltage output of the multiple voltage regulators.

In some implementations, the power management integrated circuit comprises an data interface configured to provide output indicating the determined power output levels to an external device.

In some implementations, the power management integrated circuit is configured to provide the output indicating the determined power output levels to a processor, a memory device, or a system on a chip.

In some implementations, the power management integrated circuit includes one or more external contacts each configured to receive an analog signal indicative of electrical current for a corresponding external channel. The power determination circuitry is configured to determine a power output level for each of the one or more external channels based on a digital representation of the analog signal indicative of electrical current for the corresponding external channel.

In some implementations, comprising one or more additional external contacts each configured to receive an analog signal indicative of a voltage for a corresponding external channel. The power determination circuitry is configured to determine a power output level for each of the one or more external channels based on (i) a digital representation of the analog signal indicative of electrical current for the corresponding external channel and (ii) a digital representation of the analog signal indicative of voltage for the corresponding external channel.

In some implementations, the power management integrated circuit is configured to sequentially generate digital signals from analog signals received through different external contacts using the analog multiplexer and the analog-to-digital converter.

In some implementations, the power management integrated circuit is configured to sequentially generate digital signals from analog signals received through different external contacts using a second analog multiplexer and a second analog-to-digital converter.

In some implementations, the power management integrated circuit includes multiple accumulators each configured to calculate electrical energy provided over time by a different one of the multiple voltage regulators.

In some implementations, the analog-to-digital converter has a full scale range for mapping analog input to digital output. The multiple voltage regulators provide, to the analog multiplexer, analog input signals on different scales relating the input scales to current levels, such that the highest input level in the full scale range represents different current levels for different voltage regulators. The power determination circuitry is configured to access data indicating differing scaling of digital values from the analog-to-digital converter with respect to current levels for different voltage regulators.

In some implementations, the power determination circuitry comprises multiple inputs to receive digital signals. The power management integrated circuit comprises switch circuitry configured to selectively direct output of the analog-to-digital converter to different inputs of the power determination circuitry. The control circuitry is configured to control operation of the switch circuitry to provide output of the analog-to-digital converter corresponding to each voltage regulator to the corresponding input of the power management integrated circuit corresponding to the voltage regulator.

In some implementations, the power determination circuitry is configured to determine and provide output data indicating at least one of voltage, current, charge, power, or energy of each of the multiple voltage regulators.

In some implementations, the power determination circuitry is configured to determine a power level for at least one channel that represents combined output of multiple regulators providing power for a same power domain.

In some implementations, the power management integrated circuit is configured to accumulate current and/or power measurement data over time without interaction with an external processor.

In some implementations, the power management integrated circuit is configured to: determine that a monitored electrical property exceeds a threshold value; and inform an external device that the output exceeds the threshold value.

In some implementations, the power management integrated circuit is configured to compute and accumulate average power data and/or average current data for each of one or more monitored channels or for a combination of channels without interaction with an external processor.

In some implementations, the power management integrated circuit includes a read-out buffer, and the power management integrated circuit is configured to transfer accumulated measurement data to the read-out buffer for output to an external device, without interrupting monitoring and data accumulation by power management integrated circuit.

In another general aspect, a method includes: receiving, by a power management integrated circuit comprising multiple voltage regulators, analog signals indicating current output for multiple channels, wherein at least some of the multiple channels respectively correspond to different voltage regulators of the multiple voltage regulators; selecting, by the power management integrated circuit, from among the analog signals using one or more analog multiplexers such that the analog signals for different channels are passed to the output of the one or more analog multiplexers in successive periods; determining, by the power management integrated circuit, digital representations for the analog signals respectively output by the one or more analog multiplexers in the successive periods; determining, by the power management integrated circuit, power levels for the multiple channels; and providing, by the power management integrated circuit, output data indicating power levels of the multiple channels to one or more external devices.

In some implementations, the method includes sending, by the power management integrated circuit, selection signals to the one or more analog multiplexers over multiple monitoring cycles, wherein during each monitoring cycle the selection signals cause each of multiple inputs of the one or more analog multiplexers to be successively selected with the selection being changed by the control circuitry at a predetermined rate.

In some implementations, the method includes operating the control circuitry to cause the one or more analog multiplexers to repeatedly cycle through the selection of each of multiple inputs of the one or more analog multiplexers in a series of measurement periods, wherein the selection from the multiple inputs is changed after each measurement period.

In some implementations, the measurement periods have substantially equal durations.

In some implementations, the method includes: receiving instructions or control data; and in response to receiving the instructions or control data, changing a rate of changing the selection of which input, from among the multiple inputs of the one or more analog multiplexers, is passed to the output of the one or more analog multiplexers.

In some implementations, the power management integrated circuit is capable of monitoring power output for each of a plurality of channels. The method comprises selectively monitoring, by the power management integrated circuit, a proper subset of the plurality of channels.

In some implementations, at least some of the plurality of channels respectively correspond to the multiple voltage regulators, the power management integrated circuit being configured to selectively monitor the channels by controlling the one or more analog multiplexers to select of inputs corresponding to one or more of the multiple voltage regulators.

In some implementations, the method includes: receiving, by the power management integrated circuit, voltage data from the multiple voltage regulators indicating output voltages of the multiple voltage regulators; and determining, by the power management integrated circuit, power output levels for the multiple voltage regulators based on (i) the digital outputs of the analog-to-digital converter indicating current output of the multiple voltage regulators, and (ii) the voltage data indicating output voltages of the multiple voltage regulators.

In some implementations, the one or more analog multiplexers have additional inputs each configured to receive an analog input signal indicative of a voltage output by a different one of the multiple voltage regulators. The method includes: controlling, by the power management integrated circuit, the analog multiplexer to periodically change which of the analog input signals is passed to the output of the analog multiplexer by varying selection from among a set of inputs comprising the multiple inputs and the additional inputs; and determining, by the power management integrated circuit, power output levels for the multiple voltage regulators based on (i) the digital outputs of the analog-to-digital converter indicating current output of the multiple voltage regulators, and (ii) the digital outputs of the analog-to-digital converter indicating voltage output of the multiple voltage regulators.

In some implementations, the method includes providing, by the power management integrated circuit, output indicating the determined power output levels to an external device.

In some implementations, the method includes providing, by the power management integrated circuit, output indicating the determined power output levels to a processor, a memory device, or a system on a chip.

In some implementations, the method includes: receiving, by the power management integrated circuit, an analog signal indicative of electrical current for an external channel through one or more external contacts of the power management integrated circuit; and determining, by the power management integrated circuit, a power output level for each of the one or more external channels based on a digital representation of the analog signal indicative of electrical current for the corresponding external channel.

In some implementations, the method includes: receiving, by the power management integrated circuit, an analog signal indicative of voltage for the external channel through one or more external contacts of the power management integrated circuit; and determining, by the power management integrated circuit, a power output level for each of the one or more external channels based on (i) a digital representation of the analog signal indicative of electrical current for the corresponding external channel and (ii) a digital representation of the analog signal indicative of voltage for the corresponding external channel.

In some implementations, the method includes generating, by the power management integrated circuit, digital signals from analog signals received through different external contacts using a first analog multiplexer and a first analog-to-digital converter.

In some implementations, the method includes sequentially generating, by the power management integrated circuit, digital signals from analog signals received through different external contacts using a second analog multiplexer and a second analog-to-digital converter.

In some implementations, the method includes using, by the power management integrated circuit, multiple accumulators to calculate at least one of electrical energy, current, charge, or power provided over time by a different one of the multiple voltage regulators.

In some implementations, the analog-to-digital converter has a full scale range for mapping analog input to digital output. The method includes: providing, by the multiple voltage regulators to the analog multiplexer, analog input signals on different scales relating the input scales to current levels, such that the highest input level in the full scale range represents different current levels for different voltage regulators; and accessing, by the power management integrated circuit, data indicating differing scaling of digital values from the analog-to-digital converter with respect to current levels for different voltage regulators.

In some implementations, the power determination circuitry includes multiple inputs to receive digital signals. The method includes: using, by the power management integrated circuit, switch circuitry to selectively direct output of the analog-to-digital converter to different inputs of the power determination circuitry; and controlling, by the power management integrated circuit, operation of the switch circuitry to provide output of the analog-to-digital converter corresponding to each voltage regulator to the corresponding input of the power management integrated circuit corresponding to the voltage regulator.

In some implementations, the method includes determining, by the power management integrated circuit, output data indicating at least one of voltage, current, charge, power, or energy of each of the multiple voltage regulators.

In some implementations, the method includes determining, by the power management integrated circuit, a power level for at least one channel that represents combined output of multiple regulators providing power for a same power domain.

In some implementations, the method includes accumulating, by the power management integrated circuit, current and/or power measurement data over time without interaction with an external processor.

In some implementations, the method includes: determining, by the power management integrated circuit, that a monitored electrical property exceeds a threshold value; and informing, by the power management integrated circuit, an external device that the output exceeds the threshold value.

In some implementations, the method includes computing and accumulating, by the power management integrated circuit, average power data and/or average current data for each of one or more monitored channels or for a combination of channels without interaction with an external processor.

In some implementations, the method includes transferring, by the power management integrated circuit, accumulated measurement data to a read-out buffer for output to an external device without interrupting monitoring and data accumulation by power management integrated circuit.

In another general aspect, a device includes a power management integrated circuit as discussed herein. In some implementations, the device is a computing device, a mobile device, an appliance, or a vehicle. Examples of devices that can include the power management integrated circuit include a phone, a laptop computer, a tablet computer, a desktop computer, a navigation device, a wearable device, a watch, a smart watch, etc.

The details of one or more embodiments of the invention are set forth in the accompanying drawings and the description below. Other features and advantages of the invention will become apparent from the description, the drawings, and the claims.

### BRIEF DESCRIPTION OF THE DRAWINGS

FIG. 1 is a diagram showing an example of a power management integrated circuit.

FIG. 2 is a diagram showing examples of power calculations of the power management integrated circuit.

FIG. 3 is a diagram showing another example of a power management integrated circuit.

FIG. 4 is a diagram showing another example of a power management integrated circuit.

Like reference numbers and designations in the various drawings indicate like elements.

### DETAILED DESCRIPTION

In general, PMICs are integrated circuits that perform various functions related to power management for electronic devices. For example, a PMIC may perform DC-to-DC conversion, battery charging, power source selection, voltage scaling, and so on. PMICs may also provide advanced features such as configurability, programmability, high levels of integration and efficiency. As discussed below, in addition to power management, a PMIC can include integrated power monitoring functionality that can enhance the power operation of battery-operated devices such as mobile phones, portable media players, and other electronic devices. For example, the integrated monitoring functionality can provide fine-grained monitoring on an ongoing basis as a device is used, allowing the PMIC to indicate how much power is used by various different components of the device (e.g., display, Wi-Fi, cellular radio, GPS receiver, central processing unit (CPU), and so on). With accurate fine-grained information about the power consumed for different portions of a device, the PMIC and/or another processor of the device (e.g., a microcontroller) can tailor operation to maximize battery life and operating speed.

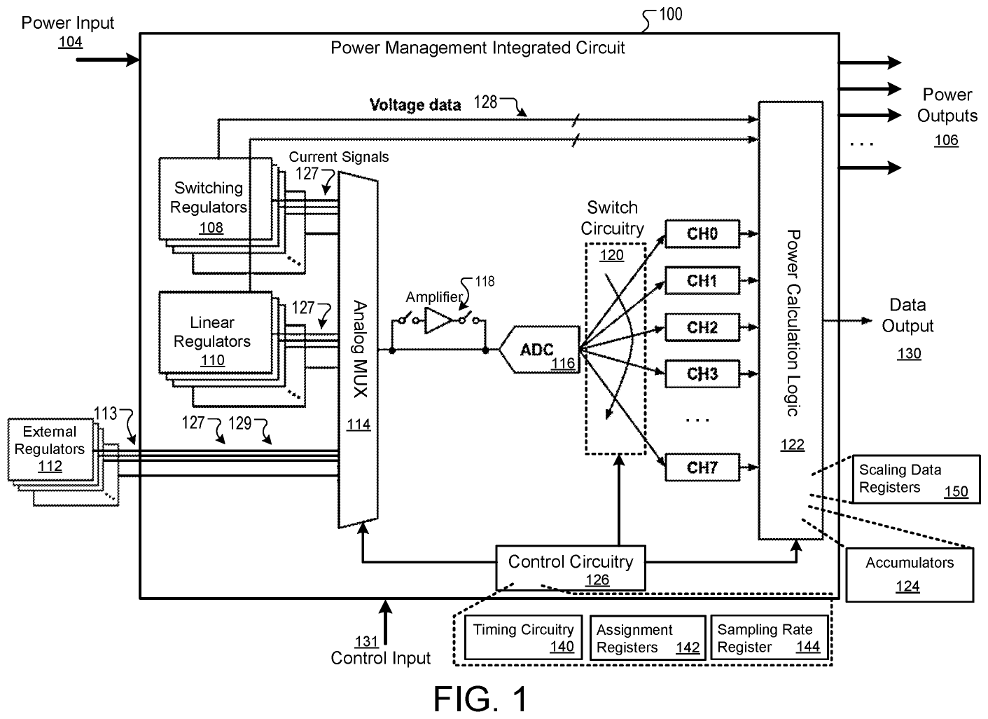

FIG. 1 is a diagram showing an example of a power management integrated circuit (PMIC) 100. The PMIC 100 is integrated circuit that include multiple power rails and power management functions within a single chip. The PMIC 100 is configured to receive DC power input 104 and generate power outputs 106 at one or more voltage levels. For example, the PMIC 100 may receive power input 104 from a battery, a battery charger circuit, a voltage regulator, or other circuitry of a device, and the PMIC 100 generates power outputs 106 for different power rails, e.g., different voltage levels to power different components or power domains of the device. The power outputs 106 may be provided to various other components of a device, such as a system-on-a-chip (SoC), a radio module, a GPS module, a display module, and so on. The elements of the PMIC 100 can all be provided within a single chip. In some implementations, one or more elements of the PMIC 100 may be provided on a separate chip. For example, the power calculation logic 122 and/or control circuitry 126 may optionally be provided on a separate chip. Similarly, data registers, buffers, accumulators, and other supporting circuitry may optionally be provided separate from the chip that includes other elements of the PMIC 100.

The PMIC 100 monitors the power transferred over some or all of the different power rails supplied by voltage regulators on the PMIC 100. The PMIC 100 can also receive inputs indicating voltage and current of external devices 112, such as voltage regulators that are not part of the PMIC 100. To receive signals indicating power for external devices 112, the PMIC 100 package can include electrical contacts 113, such as balls, pins, or pads, that can be coupled to receive signals indicating current and/or voltage of external power rails.

The PMIC 100 includes circuitry to convert input voltage to one or more output voltages and monitor each of the output power rails. As shown in FIG. 1, the PMIC 100 can include one or more voltage regulators, such as one or more switching regulators 108 and/or one or more linear regulators 110. These regulators 108, 110 provide the power outputs 106 that are output from the PMIC 100. FIG. 1 omits illustration of the connections between the voltage regulators 108, 110 to the power outputs 106 simply for clarity in illustrating the power monitoring features of the PMIC 100.

To determine the power output by the different power rails, the PMIC 100 includes power determination circuitry, shown as power calculation logic 122, that is configured to concurrently monitor power for multiple channels, using a time-division multiplexing approach. In FIG. 1, the power calculation logic 122 determines power for eight channels, labelled CHO to CH7. In the example of FIG. 1, all the regulators 108, 110, 112 are available to be selected for power monitoring, but only a total of 8 channels can be monitored at a time. In general, however, the PMIC 100 architecture is not limited to using this particular number of channels. The PMIC 100 may include more than 8 channels for power monitoring. The PMIC 100 is configured to provide data output 130, such as on a serial data interface, indicating the monitored power for the different channels. For example, the PMIC 100 can be arranged to provide output data indicating power levels to a processor, a SoC, a memory device, or other external component.

To determine power output for a rail, the power calculation logic 122 uses information about the voltage and current for the rail. Information about current levels is provided from the regulators 108, 110 to the power calculation logic 122 through an analog multiplexer 114, an analog-to-digital convertor (ADC) 116, and switch circuitry 120. In the example of FIG. 1, voltage information is provided from the regulators 108, 110 to the power calculation logic 122 as digital data through voltage data lines 128. For example, this information can be read from registers of the regulators 108, 110 to indicate current voltage settings of the regulators 108, 110.

The power calculation logic 122 can be used to determine power characteristics for external power rails. For monitoring power of external power rails, signals indicative of external power rail current levels can be provided to the analog multiplexer 114. In many cases, signals indicative of voltage levels for the external power rails are also provided to the multiplexer 114. Of course, although the multiplexer 114 is shown as a single multiplexer, the functionality may be implemented using multiple multiplexers.

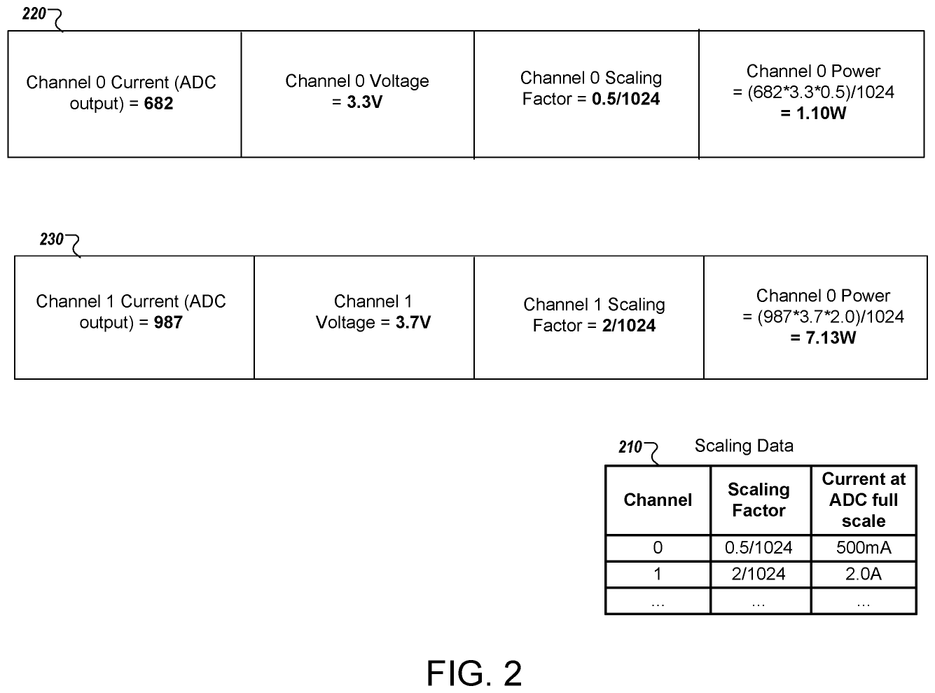

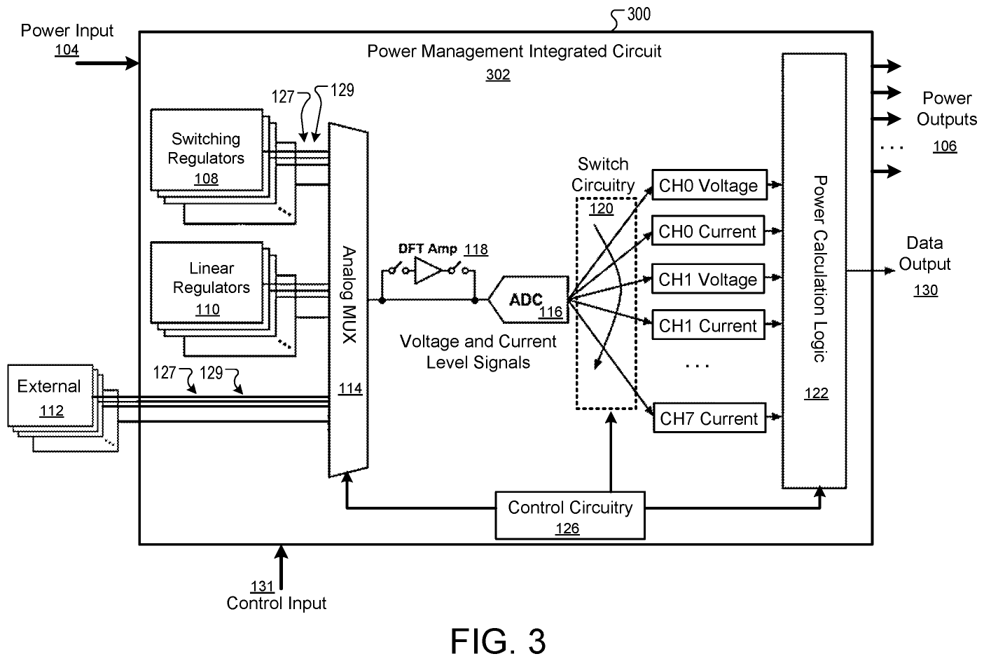

The power calculation logic 122 can determine and output data indicating any of various types of electrical characteristics, such as voltage, current, charge, power, and energy, for voltage regulators of the PMIC 110 (e.g., regulators 108, 110) and/or for external power rails (e.g., signals for external regulators 112). Voltage information can be obtained through voltage data lines 128 for internal regulators. Voltage information can also be obtained through separate inputs to the multiplexer 114, with individual channels to the power calculation logic 122. This technique can be used for monitoring the external rails or external regulators 112, and may also be used for monitoring internal regulators 108, 110 as shown in FIG. 3. Current information is obtained through the inputs to the multiplexer from the regulators 108, 110, 112, converted to digital form, and then provided in different channels to the power calculation logic 122. Power can be determined by the power calculation logic 122 as the product of voltage and current. Energy can be determined as the product of power and time. Charge can be determined as the product of current and time. As explained with respect to FIG. 2, the calculations can further include scaling factors or adjustment factors, for example, to account for scaling of inputs done to maximize the use of the range of the ADC 116.

The PMIC 100 also includes control circuitry 126 that manages the power monitoring process, for example, controlling selections of the analog multiplexer 114, controlling operation of the switch circuitry 126, and coordinating timing and channel assignment with the power calculation logic 122. The control circuitry 126 determines which inputs to the analog multiplexer 114 to monitor, as well as the sampling rate or switching rate to change selection among them. The control circuitry 126 sends signals to analog multiplexer 114 for changing the selection of signals to be passed to the ADC 116, directs the switch circuitry 120 to assign output of the ADC 116 to the correct power monitoring channels, and informs the power calculation logic 122 of these settings as well as others such as the sampling rates or measurement period durations, regulator and channel assignments, etc.

The power monitoring functions of the PMIC 100 can be adjustable or programmable to allow different sets of power rails to be monitored at different times. For example, during one mode of operation of a device, a first set of voltage regulators may be monitored. During a second mode of operation of the device, a second set of voltage regulators may be monitored. Of course, the PMIC 100 may be designed to allow all regulators to be monitored on an ongoing basis, but this is not required. The PMIC 100 can be configured to receive input from a processor (e.g., a microcontroller, a central processing unit, etc.), a SoC, or another external device that specifies or changes the set of voltage regulators or power rails to be monitored. The control circuitry 126 may include registers or other elements to store different programmable parameters for power monitoring. For example, assignment registers 142 may store data indicating which power rails are selected for monitoring and which channels, CH0 to CH7, the different rails are assigned to for monitoring purposes. Similarly, a sampling rate register 144 may store data indicating the rate at which the PMIC 100 should switch between the measurement of different channels. These and other parameters can be set and adjusted through input from a connected processor or SoC, for example through control input 131 over a digital control interface.

As shown in FIG. 1, the multiplexer 114 has multiple inputs, and the multiplexer 114 only passes the signal from one of the inputs to the output of the multiplexer 114 at a time. Each of the regulators 108, 110 is connected to a different input of the multiplexer 114, and the output provided is an analog current level signal 127 indicating the level of current presently output by the regulator. Each of the external regulators 112 also is connected to a different input of the multiplexer 114 to provide an analog current level signal 127. In addition, the external regulators 112 can each be connected to a second input of the analog multiplexer 114 to provide voltage level signals 129, because voltage data may not be available from external regulators 112 in the same manner as from the internal regulators 108, 112.

Note that the signals 127, 129 provided to the inputs of the analog multiplexer 114 are not the direct power outputs of the regulators 108, 110, 112. Instead, the signals 127 are voltages that represent or indicate the current levels output by the various regulators. For example, the signal 127 for a regulator may be generated using a current follower stage that tracks the output of the regulator, or using a current sense resistor. As discussed below, the signals 127 may be scaled differently, so that each uses the full scale input range of the ADC 116 even though typical output current ranges for the regulators may be different. The signals 129 that indicate voltage of external rails also are not necessarily the output voltages themselves. For example, the output voltage of a regulator may be scaled with a voltage divider or otherwise adjusted to fit within a full scale input range of the ADC 116.

Once the set of power rails to be monitored is selected and the assignment of rails to channels is stored in the assignment registers 142, the control circuitry 126 controls the analog multiplexer 114 to successively change which input of the analog multiplexer 114 is selected and passed to the ADC 116. For example, the control circuitry 126 can generate and provide selection signals to the analog multiplexer 114. These selection signals can be varied at the sampling rate stored in the sampling rate register 144, for example, at 5 kHz, 1kHz, 500Hz, etc. The control circuitry 126 can include timing circuitry 140 to generate or receive a clock signal and derive appropriate timing signals for the current sampling rate.

The control circuitry 126 can generate the selection signals to cause the analog multiplexer 114 to select the inputs for the appropriate channels to monitor, one at a time. For example, the control circuitry 126 can issue a series of selection signals that cause the analog multiplexer 114 to sequentially select the inputs corresponding to the monitored regulators in a round robin fashion. Once each input has been selected for at least one measurement period, the process repeats on an ongoing basis and each of the inputs are sampled again in turn. As an example, if eight voltage regulators VR0 to VR7 are selected for monitoring, the control circuitry 126 can send a series selection signals that cause the current level signals 127 for VR0, VR1, VR2, . . . , VR7 to be respectively selected and passed to the ADC 116 in turn. Once each voltage regulator's current signal is determined, the cycle repeats to measure the current at each of the voltage regulators again.

As the control circuitry 126 changes which input to the analog multiplexer is selected, the control circuitry can also send corresponding signals to the switch circuitry 120 and power calculation logic 122 so that the output of the ADC 116 is correctly routed and interpreted. Because the output of the ADC 116 may potentially relate to any of the channels monitored, depending on the timing of the output, the PMIC 100 includes switch circuitry 120 to route the output of the ADC 116 to the input for the appropriate channel. In the example, the power calculation logic 122 receives data for each channel through a different input, and the switch circuitry 120 acts as a decoder to distribute the output of the ADC 116 to the respective channel inputs.

The control circuitry 126 provides control signals to the switch circuitry 120 (e.g., decoder) in synchronization with the selection signals provided to the analog multiplexer 114. This can ensure that the selection of analog input values provided to the analog multiplexer 114 matches the routing of output data from the ADC 116. For example, if the current level signal 127 for voltage regulator VRO is assigned to channel CH3, the control circuitry 126 can ensure that when the input for voltage regulator VRO is provided to the ADC 116, the output of the ADC 116 is routed to the input of power calculation logic 122 that corresponds to channel CH3. When the selection signal to the analog multiplexer 114 changes, the control circuitry can also change the control signals to the switch circuitry 120 to re-route the output of the ADC 116 to the appropriate channel's input. This coordination among the input and output of the ADC 116 can be very important, especially where the selection of which power rails are monitored and which monitoring channels they are assigned to can vary dynamically.

In some implementations, the function of distributing or assigning ADC outputs to the different channels can be done in other ways besides physically routing signals to different inputs or portions of a circuit. For example, rather than routing the output of the ADC 116 to different physical inputs or data lines, the output of the ADC 116 may be provided to a single input of the power calculation logic 122, along with a code specifying the channel (e.g. from among CHO to CH7) to which the presently available ADC output corresponds. The power calculation logic may then use the channel code to associate the received ADC output to the correct monitoring channel.

As noted above, the power calculation logic 122 may receive voltage data for some or all of the internal regulators 108, 110 through voltage data lines 128. In some implementations, each of the internal regulators 108, 110 may have a dedicated data line for delivering its output voltage data.

If digital data indicating voltages of external rails or external regulators 122 is available, the PMIC 100 can be designed to include a data interface to receive voltage level data for those external elements also. Nevertheless, in many cases it may be preferable to receive analog voltage level signals 129 and convert them to digital values using the ADC 116. In this case, as discussed further below, monitoring power for an external rail or an internal voltage regulator that does not provide voltage data would require two inputs to the analog multiplexer and two sampling intervals, one for a current level signal 127 and a second for a voltage level signal 129.

The power calculation logic 122 uses the voltage and current data for each channel to determine a power level for the channel. In general, power can be calculated by multiplying values representing voltage and current. However, the analog signals 127, 129 and the output values from the ADC 116 may be scaled differently for different channels, and so the power calculation logic 122 may store, retrieve, and use one or more scaling factors to make channel-specific adjustments when determining power levels. The power calculation logic 122 may include scaling data registers 150 that indicate scaling factors or other data corresponding to each channel CH0 to CH7.

Different regulators 108, 110, 112 may scale their analog current and voltage signals 127, 129 differently to take better advantage of the full scale input range of the ADC 116. For different regulators using different scaling, the same values of input and output to the ADC 116 may represent different levels of current. For example, the full scale input range for the ADC 116 may be 0V to 1V. Current for a first regulator may fall in a range from 0 mA to 500 mA, while the current for another regulator may fall in a range from 0A to 3A. To provide the greatest resolution for each regulator with the same ADC 116, despite the significant difference in magnitude of typical currents, the analog current level signals 127 can be scaled differently. The first regulator can provide signals 127 so that 1V represents the 500 mA maximum current for the first regulator, and the second regulator can provide signals 127 where 1V represents the 3A maximum for the second regulator. Using a 10-bit ADC for the ADC 116, this would allow current levels to be resolved in approximately 0.5 mA increments for the first regulator, and in approximately 3 mA increments for the second regulator.

Because the assignment of regulators or rails to different channels is variable, the scaling factors for the different channels can also be programmable and adjustable by the PMIC 100. In some cases, the PMIC 100 includes standard or default scaling values for one or more internal regulators 108, 110, for example, in non-volatile storage, read-only memory, or other embedded memory. The power calculation logic 122 and/or the control circuitry 126 can identify the regulator assigned to a particular channel, retrieve the scaling factor(s) for the regulator, and load the retrieved scaling factor(s) into the scaling data register 150 for the particular channel so that the appropriate scaling will be used by the power calculation logic 122 when calculating power for that channel.

As mentioned above, power is monitored on an ongoing basis for each of the channels, CHO to CH7, that have a voltage regulator 108, 110, 112 or power rail assigned to be monitored. The power calculation logic 122 can include or be in communication with one or more memory devices to store various measurements of current and voltage levels and/or power calculations for each channel. As new values for each channel are determined, e.g., as the control circuitry 126 causes the analog multiplexer 114 to cycle through the different inputs selected for monitoring, the power calculation logic 122 generates new power calculations for each channel and stores them so they are available over the data output interface providing data output 130. The power calculation logic 122 may provide power data in any appropriate way, for example, on-demand in response to a request from a connected device, at predetermined time intervals, and/or in response to a detected condition (e.g., the power calculation logic 122 determining that voltage, current, power, and/or energy for one or more channels satisfies a threshold or fails to satisfy a threshold).

The power calculation logic 122 can include one or more accumulators 124 to monitor the energy provided on a channel over time. For example, an accumulator 124 can be included for each channel, CHO to CH7. The power calculation logic 122 may configured to measure energy over a period time using the accumulators, which can provide increased efficiency of a device. For example, during a low-power mode, the main processor of a SoC may be powered down and the PMIC 100 may use the accumulators 124 to determine power expended over a period of time, e.g., 5 minutes or 15 minutes, for each power monitoring channel. This can use far less power than requiring a central processing unit to remain active and repeatedly obtain power measurements over the period. At the end of the period, the PMIC 100 can provide the energy expended over the period, allowing the connected processor to wake up briefly to receive and process the data. The PMIC 100 then begins energy measurement over a new period in the same manner.

Using the accumulators 124, the PMIC 100 has the ability to accumulate measurements for power, current, energy, charge, etc. over extended periods of time (e.g., minutes, hours, or days, depending on the design) without intervention from an external processor (e.g., microcontroller). This allows the PMIC 100 to provide power-awareness with no gaps in monitoring, at a very low battery-life cost to run the monitoring functions. This allows the PMIC 100 to continue monitoring power, current, and other quantities while a SoC, a processor, and/or other portions of a device are powered off or in a low-power mode (e.g., sleep mode, etc.). Similarly, the power calculation circuitry 122 of the PMIC 100 enables the PMIC 100 to compute and accumulate average power, average current, and other averaged data, not only raw or instantaneous data, and to do so without any control or intervention by an external processor (e.g., microcontroller, SoC, etc.).

The power calculation circuitry 122 can be configured to monitor power parameters, e.g., to monitor specific quantities (e.g., power, current, voltage, charge, energy, etc.) for specific channels. The power calculation circuitry 122 can be configured to compare monitored parameters with corresponding thresholds or reference values, and to notify a processor or other external element is a measurement satisfies the threshold (e.g., crosses the threshold, exceeds the threshold, falls below the threshold, etc.). For example, the PMIC 100 can receive instructions, through control input 131, from an external processor. The instructions can be to monitor one or more electrical properties for one or more channels, and the control input 131 can provide one or more thresholds for comparison. The PMIC 100 can use the power calculation circuitry 122 to determine when any of the monitored quantities exceed the corresponding threshold(s), and then inform an SoC or external processor through the data output 130.

To facilitate data read-out from the PMIC 100, the PMIC 100 can include one or more read-out buffers. The PMIC 100 is configured to transfer accumulated measurement data to the read-out buffer for output to an external device (e.g., a processor, SoC, etc.) without interrupting monitoring and data accumulation by the PMIC 100. The PMIC 100 can thus capture a snapshot of accumulator data (e.g., for power, current, charge, energy, etc.) to be transferred over the output interface to the processor, while the accumulators 124 and the power calculation circuitry 122 continue running uninterrupted. This can provide seamless monitoring of data even with output data transfers, where monitoring is not disrupted by the time required to move data over a speed-limited serial interface. In some implementations, when an external device triggers output of accumulated data (e.g., by writing a bit to a control register, sending an instruction, etc.) or output is triggered by the passage of time (e.g., in the case of scheduled or periodic outputs), a snapshot of the accumulator data is placed in the read-out buffer(s), where it can then be read by an external device or otherwise transferred. When the data is copied to the read-out buffer(s), the accumulators 124 and/or associated counters are reset (e.g., re-initialized to zero), but keep counting up to accumulate new data without interruption. The data in the read-out buffer can be accessed without worrying about interfering with the ongoing measurements in progress.

In some implementations, the PMIC 100 can vary the rate at which the control circuitry 126 changes the selection from among the different inputs of the analog multiplexer 114. For example, the rate may be lowered to reduce power consumption, since this would result in fewer measurements and less calculation. On the other hand, if desired, the rate may be increased to provide higher resolution of power data with more frequent measurements. The rate selected may be different for different operating modes or conditions of the device including the PMIC 100, or based on control input from a SoC or other component of the device. In many applications, an appropriate rate for switching between is in the range of approximately 200 Hz to 10 kHz, although the rate may vary depending on a number of factors, such as power consumption targets, the response time of circuitry, the number of channels to be monitored concurrently, and so on.

In some implementations, the PMIC 100 includes an amplifier 118 which can be used to allow enhanced testing of a device including the PMIC 100 by the device manufacturer. In actual use, the amplifier 118 may be disconnected, e.g., removed from the circuit path with fuses or switches, so that the amplifier 118 does not affect signals from the analog multiplexer 114 to the ADC 116. After manufacturing a device including the PMIC 100, however, the amplifier 118 may be coupled in the path between the analog multiplexer 114 to the ADC 116 and used to test for small leakage currents. For example, the amplifier 118 can be enabled for a self-test. Channels that are not actively being used can be selected, with their current signals amplified with the amplifier 118. Many failures such as short circuits, cracked capacitors, and so on may result in leakage current that does not result in a catastrophic failure of the system but would nevertheless result in unsatisfactory power drain and low battery life for a user. The amplifier 118 amplifies current signals so that even small leakage amounts due to manufacturing defects can be identified.

For example, at the manufacturing process for the PMIC 110 or a device that includes the PMIC 110, the device may be powered on but placed into sleep mode or another low-power state. The various regulators 108, 110, 112 can be turned on and measured one-by-one to determine current levels and power levels during the low-power mode. The power calculation circuitry 122 or a connected device can compare the detected current and/or power levels in the low-power state to acceptable baseline levels, to determine whether there are any manufacturing defects that have caused excessive current leakage. Using the amplifier 118, very small leakage currents can be detected, for example on the order of 100mA or less in many cases. If the measurements during testing show that current levels are appropriate, the amplifier 118 can be fused off or otherwise disabled so that future power monitoring is performed without the amplifier 118 (e.g., as illustrated in FIG. 1).

FIG. 2 is a diagram showing an example of power calculation by the PMIC 100. The power calculation is performed by the power calculation logic 122 on PMIC 100, for example, by multiplying the current value from the ADC 116 and a voltage value received through voltage data channels 128. For the power calculation, different input channels may have different scaling factors for use with output of the ADC 116. For example, a 10-bit ADC can provide 1024 different output levels. For channel 0, the highest output value may represent 500 mA, resulting in a scaling factor of 0.5/1024. For channel 1, the highest output value may represent 2.0A, resulting in a different scaling factor of 2/1024. The example scaling factors and other data are shown as a table 210, and this data can be stored by the PMIC 100, such as in scaling data registers 150.

Two examples 220, 230 of power calculations are shown. Power can be calculated as, for example, Channel Power=Channel current * Channel Voltage * Channel Scaling Factor. In the first example 220, the ADC output value representing current is “682” and the input voltage is 3.3V. The calculated channel 0 power equals to (682*3.3*0.5)/1024=1.10W. In the second example 230, the ADC output value representing current is “987” and the input voltage is 3.7V. The calculated channel 0 power equals to (987*3.7*2.0)/1024=7.13W. The examples show how different regulators can make use of the full range of the ADC 116 across significantly different current levels.

FIG. 3 is a diagram showing another example of a PMIC 300. The PMIC 300 is generally arranged in the same manner as PMIC 100 of FIG. 1 and can include the features discussed for the PMIC 100, but in PMIC 300 the regulators 108, 110 do not output digital voltage data to the power calculation logic 122. Instead, the regulators 108, 110 provide analog signals indicating their output voltages to the analog multiplexer 114, and voltage data is provided to the power calculation logic 122 by the same ADC 116 used to convert the analog current level signals. As a result, for each regulator or rail to be monitored (e.g., for both internal regulators 108, 110 and external regulators 112), there are two analog signals converted using the ADC 116. As a result, the number of values received is twice the number of regulators or rails to be monitored. If there are 8 regulators to be monitored, for example, the PMIC 300 repeatedly cycles through the selection of 16 different inputs of the analog multiplexer 114.

In the illustrated example, the control circuitry 126 steps through the selection of multiplexer 114 inputs respectively providing for voltage and current signals 127, 129 for the regulators selected to be monitored. The control circuitry 126 also controls the switch circuitry 120 to direct the output of the ADC 116 to the appropriate channel and whether the output represents a voltage or current, so that the output of the ADC 116 is appropriately interpreted by the power calculation logic 130.

For example, in a first measurement, the control circuitry 126 causes the analog multiplexer 114 to select the input for the voltage level signal 129 for channel CH0, and the digital representation from the ADC 116 is designated as a voltage value for channel CH0. The value is stored so it can be used with the corresponding current value obtained later. In the next cycle, the control circuitry 126 causes the analog multiplexer 114 to select the input providing the current level signal 127 for channel CH0, and the digital representation from the ADC 116 is designated as a current value for channel CH0. The control circuitry 126 then changes the input selection of the analog multiplexer in successive periods to provide the voltage signal 129 for channel CH1, the current signal 127 for channel CH1, the voltage signal 129 for channel CH2, the current signal 127 for channel CH2, and so on until each of the voltage and current signals for each monitored regulator or rail has been converted. Then the control circuitry 126 repeats the monitoring process by cycling through each of the voltage and current signals for an updated measurement.

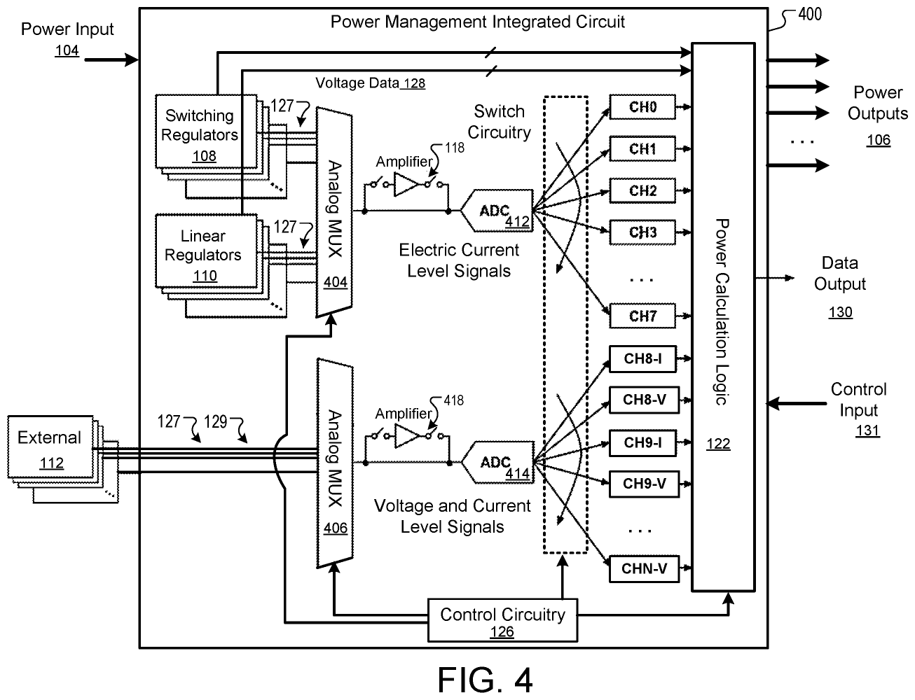

FIG. 4 is a diagram showing another example of a PMIC 400. The PMIC 400 has features as discussed for PMIC 100 above, but uses two analog multiplexers 404, 406 and two ADCs 412, 414 rather than one multiplexer 114 and one ADC 116 as in FIG. 1. The PMIC 400 uses one multiplexer 404 and ADC 412 for monitoring power of internal regulators 108, 110. The PMIC 400 uses another multiplexer 406 and ADC 414 for monitoring external regulators 112.

As described for PMIC 100, the PMIC 400 obtains voltage data over voltage data lines 128 for the internal regulators 108, 110. For monitoring the external regulators 112, the PMIC 400 obtains voltage signals and current signals and provides both for conversion to digital values through the ADC 414.

The use of two multiplexers 404, 406 and two ADCs 412, 414 enables monitoring on both internal and external channels to occur at the same time. In other words, the control circuitry 126 can cycle through different inputs of analog multiplexer 404 at the same time that it cycles through different inputs of analog multiplexer 406.

In some implementations, using multiple multiplexers and multiple ADCs can allow the power monitoring functionality to scale to monitor larger numbers of channels or to sample each channel at a faster rate. In some implementations, one of the advantages of using a different ADC 414 for external power rails than for internal power rails is that the ADC 414 can be tuned to have a different full scale input voltage range to allow monitoring of a wider range of inputs, although potentially with the tradeoff of lower resolution. While the internal regulators 108, 110 can be designed with control over the magnitude and type of current signals 127 provides, there may be less flexibility for signals 127, 129 received from outside the PMIC 400. Accordingly, the ADC 414 may be configured to accept a larger range of input voltages, compared to the ADC 412, without reaching the maximum digital output level for the ADC 414. Other options can be used to scale input signals 127, 129 for external regulators 112, but these approaches may involve resistors and other additional off-chip components.

A number of implementations have been described. Nevertheless, it will be understood that various modifications may be made without departing from the spirit and scope of the disclosure. For example, various forms of the flows shown above may be used, with steps re-ordered, added, or removed.

Embodiments of the invention and all of the functional operations described in this specification can be implemented in electronic circuitry, or in computer software, firmware, and/or hardware, including the structures disclosed in this specification and their structural equivalents, or in combinations of one or more of them. A power management integrated circuit can be implemented as a mixed-signal chip (e.g., a CMOS integrated circuit) that includes analog, digital, and mixed-signal circuits, as well as potentially firmware or embedded software. For example, operations of the control circuitry may be implemented using digital circuitry, an FPGA (field programmable gate array) or other programmable logic device, a processor and corresponding software, and so on.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

While this specification contains many specifics, these should not be construed as limitations on the scope of the invention or of what may be claimed, but rather as descriptions of features specific to particular embodiments of the invention. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

In each instance where an HTML file is mentioned, other file types or formats may be substituted. For instance, an HTML file may be replaced by an XML, JSON, plain text, or other types of files. Moreover, where a table or hash table is mentioned, other data structures (such as spreadsheets, relational databases, or structured files) may be used.

Particular embodiments of the invention have been described. Other embodiments are within the scope of the following claims. For example, the steps recited in the claims can be performed in a different order and still achieve desirable results.

What is claimed is:

1. A power management integrated circuit comprising:
multiple voltage regulators;
an analog multiplexer having multiple inputs and an output, wherein each of the multiple inputs is configured to receive an analog input signal indicative of an amount of electrical current output by a different one of the multiple voltage regulators;
an analog-to-digital converter configured to receive analog output signals from of the analog multiplexer and to provide a digital output;
power determination circuitry configured to determine a power output level for each of the multiple voltage regulators based on respective digital outputs of the analog-to-digital converter; and
control circuitry configured to control the analog multiplexer to periodically change which of the analog input signals is passed to the output of the analog multiplexer.

2. The power management integrated circuit of claim 1, wherein, to control the analog multiplexer, the control circuitry is configured to send selection signals to the analog multiplexer over multiple monitoring cycles, wherein during each monitoring cycle the selection signals cause each of the multiple inputs to be successively selected with the selection being changed by the control circuitry at a predetermined rate.

3. The power management integrated circuit of claim 1, wherein the control circuitry is configured to cause the analog multiplexer to repeatedly cycle through the selection of each of the multiple inputs in a series of measurement periods, wherein the selection from the multiple inputs is changed after each measurement period.

4. The power management integrated circuit of claim 3, wherein the measurement periods have substantially equal durations.

5. The power management integrated circuit of claim 1, wherein the control circuitry is programmable to vary a rate of changing the selection of which input, from among the multiple inputs of the analog multiplexer, is passed to the output of the analog multiplexer.

6. The power management integrated circuit of claim 1, wherein the power management integrated circuit is capable of monitoring power output for each of a plurality of channels; and
wherein the control circuitry programmable to selectively monitor a proper subset of the plurality of channels.

7. The power management integrated circuit of claim 6, wherein at least some of the plurality of channels respectively correspond to the multiple voltage regulators, the control circuitry being configured to selectively monitor the channels by controlling the analog multiplexer to select of inputs corresponding to one or more of the multiple voltage regulators.

8. The power management integrated circuit of claim 1, wherein the power determination circuitry is configured to receive, from the multiple voltage regulators, voltage data indicating output voltages of the multiple voltage regulators; and
wherein the power determination circuitry is configured to determine power output levels for the multiple voltage regulators based on (i) the digital outputs of the analog-to-digital converter indicating current output of the multiple voltage regulators, and (ii) the voltage data indicating output voltages of the multiple voltage regulators.

9. The power management integrated circuit of claim 1, wherein the analog multiplexer has additional inputs each configured to receive an analog input signal indicative of a voltage output by a different one of the multiple voltage regulators;
wherein the control circuitry is configured to control the analog multiplexer to periodically change which of the analog input signals is passed to the output of the analog multiplexer by varying selection from among a set of inputs comprising the multiple inputs and the additional inputs; and
wherein the power determination circuitry configured to determine power output levels for the multiple voltage regulators based on (i) the digital outputs of the analog-to-digital converter indicating current output of the multiple voltage regulators, and (ii) the digital outputs of the analog-to-digital converter indicating voltage output of the multiple voltage regulators.

10. The power management integrated circuit of claim 1, wherein the power management integrated circuit comprises an data interface configured to provide output indicating the determined power output levels to an external device.

11. The power management integrated circuit of claim 10, wherein the power management integrated circuit is configured to provide the output indicating the determined power output levels to a processor, a memory device, or a system on a chip.

12. The power management integrated circuit of claim 1, comprising one or more external contacts each configured to receive an analog signal indicative of electrical current for a corresponding external channel; and
wherein the power determination circuitry is configured to determine a power output level for each of the one or more external channels based on a digital representation of the analog signal indicative of electrical current for the corresponding external channel.

13. The power management integrated circuit of claim 12, comprising one or more additional external contacts each configured to receive an analog signal indicative of a voltage for a corresponding external channel; and
wherein the power determination circuitry is configured to determine a power output level for each of the one or more external channels based on (i) a digital representation of the analog signal indicative of electrical current for the corresponding external channel and (ii) a digital representation of the analog signal indicative of voltage for the corresponding external channel.

14. The power management integrated circuit of claim 12, wherein the power management integrated circuit is configured to sequentially generate digital signals from analog signals received through different external contacts using the analog multiplexer and the analog-to-digital converter.

15. The power management integrated circuit of claim 12, wherein the power management integrated circuit is configured to sequentially generate digital signals from analog signals received through different external contacts using a second analog multiplexer and a second analog-to-digital converter.

16. The power management integrated circuit of claim 1, comprising multiple accumulators each configured to calculate electrical energy provided over time by a different one of the multiple voltage regulators.

17. The power management integrated circuit of claim 1, wherein the analog-to-digital converter has a full scale range for mapping analog input to digital output;
wherein the multiple voltage regulators provide, to the analog multiplexer, analog input signals on different scales relating the input scales to current levels, such that the highest input level in the full scale range represents different current levels for different voltage regulators; and
wherein the power determination circuitry is configured to access data indicating differing scaling of digital values from the analog-to-digital converter with respect to current levels for different voltage regulators.

18. The power management integrated circuit of claim 1, wherein the power determination circuitry comprises multiple inputs to receive digital signals;
wherein the power management integrated circuit comprises switch circuitry configured to selectively direct output of the analog-to-digital converter to different inputs of the power determination circuitry; and
wherein the control circuitry is configured to control operation of the switch circuitry to provide output of the analog-to-digital converter corresponding to each voltage regulator to the corresponding input of the power management integrated circuit corresponding to the voltage regulator.

19. The power management integrated circuit of claim 1, wherein the power determination circuitry is configured to determine and provide output data indicating at least one of voltage, current, charge, power, or energy of each of the multiple voltage regulators.

20. A method comprising:
receiving, by a power management integrated circuit comprising multiple voltage regulators, analog signals indicating current output for multiple channels, wherein at least some of the multiple channels respectively correspond to different voltage regulators of the multiple voltage regulators;
selecting, by the power management integrated circuit, from among the analog signals using one or more analog multiplexers such that the analog signals for different channels are passed to the output of the one or more analog multiplexers in successive periods;
determining, by the power management integrated circuit, digital representations for the analog signals respectively output by the one or more analog multiplexers in the successive periods;
determining, by the power management integrated circuit, power levels for the multiple channels; and
providing, by the power management integrated circuit, output data indicating power levels of the multiple channels to one or more external devices.
